(19) United States
(12) Patent Application Publication
(10) Pub. No.: US 2008/0268154 A1
(43) Pub. Date: Oct. 30, 2008

(54) METHODS FOR DEPOSITING A HIGH-K DIELECTRIC MATERIAL USING CHEMICAL VAPOR DEPOSITION PROCESS

(76) Inventors: SHREYAS KHER, Campbell, CA (US); Tejal Goyani, Sunnyvale, CA (US); Balaji Kannan, Fremont, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/742,402

(22) Filed: Apr. 30, 2007

(51) Int. Cl. C23C 16/06

(52) U.S. Cl. 427/255.34

(57) ABSTRACT

Methods for forming a high-k dielectric layer that may be utilized to form a metal gate structure in TANOS charge trap flash memories. In one embodiment, the method may include providing a substrate into a chamber, supplying a gas mixture containing an oxygen containing gas and aluminum containing compound into the chamber, wherein the aluminum containing compound has a formula selected from a group consisting of RₓAl_{y}(OR′)ₓ and Al(NRR′)₃, heating the substrate, and depositing an aluminum oxide layer having a dielectric constant greater than 8 on the heated substrate by a chemical vapor deposition process.

### BACKGROUND OF THE INVENTION

1. Field of the Invention

Embodiments of the invention generally relate to methods for depositing materials on substrates, and more specifically, to methods for depositing a high-k dielectric material on a substrate using a chemical vapor deposition process.

2. Description of the Related Art

Flash memory has been widely used as non-volatile memory for a wide range of electronic applications, such as mobile phones, personal digital assistants (PDAs), digital camera, MP3 players, USB devices, and the like. As flash memories are typically used for portable recording devices to store large amount of information, reduction in low electric power consumption and small cell sizes, along with increased operational speed, maintain a continued need for improvement in flash memory designs and manufacturing techniques.

As the device dimensions enter into a narrow scale of 50 nm or even smaller, charge trap flash memory devices have been developed to provide good sufficient coupling effect with less floating-gate interference as compared to conventional floating-gate-tunneling oxide (FLOTOX) devices. Several types of charge trap flash memory cells, including SONOS (Silicon-Oxide-Nitride-Oxide-Silicon), MONOS (Metal-Oxide-Nitride-Oxide-Silicon) and the like, have been investigated for improving the device performance. In a gate structure of a charge trap flash memory cell, multi-dielectric layers are used to form a gate dielectric layer that serves as a charge trap layer within the cell, thereby trapping electrons in interface states, resulting in good retention properties.

Recently, an aluminum oxide layer has been used in a gate structure to form a TANOS (Tantalum-Alumina-Nitride-Oxide-Silicon) metal gate charge trap flash memory that provides high work function and erase efficiency. The aluminum oxide layer performs as a blocking material that eliminates back tunneling during erase operation to provide a high erase speed and efficiency. Therefore, the newly developed TANOS cell structure having the aluminum oxide layer integrated in the cell structure has been recognized as a promising gate configuration to improve the electrical performance for charge trap flash memories.

Therefore, there is a need for a method for depositing a high-k material suitable for use in flash memories.

### SUMMARY OF THE INVENTION

Methods for forming a high-k dielectric layer on a substrate suitable for flash memory fabrication are provided. In one embodiment, a method for depositing a high-k dielectric material may include providing a substrate into a chamber, supplying a gas mixture containing an oxygen containing gas and aluminum containing compound into the chamber, wherein the aluminum containing compound has a formula selected from a group consisting of RₓAl_{y}(OR′)_{z} and Al(NRR′)₃, heating the substrate, and depositing an aluminum oxide layer having a dielectric constant greater than 8 on the heated substrate by a chemical vapor deposition process.

In another embodiment, a method for depositing a high-k dielectric material on a substrate suitable for flash memory fabrication may include providing a substrate into a chamber, vaporizing a triethyl-tri-sec-butoxy dialumium (EBDA) precursor at less than 150 degrees Celsius, supplying the vaporized precursor and an oxygen containing gas into the chamber, heating the substrate, and depositing an aluminum oxide layer on the heated substrate by a chemical vapor deposition process.

In yet another embodiment, a method for depositing a high-k dielectric material on a substrate suitable for flash memory fabrication may include providing a substrate into a chamber, supplying a gas mixture containing triethyl-tri-sec-butoxy dialumium (EBDA) precursor and an oxygen containing gas into the chamber, heating the substrate to between about 600 degrees Celsius and about 800 degrees Celsius, depositing an aluminum oxide layer having a dielectric constant greater than 8 on the heated substrate by a chemical vapor deposition process, and annealing the substrate.

### BRIEF DESCRIPTION OF THE DRAWINGS

The teachings of the present invention can be readily understood by considering the following detailed description in conjunction with the accompanying drawings, in which:

FIG. 1 depicts a schematic plan view of an exemplary integrated semiconductor substrate processing system (e.g., a cluster tool) of the kind used in one embodiment of the invention;

FIG. 2 depicts a schematic illustration of an apparatus that can be used for the practice of this invention;

FIG. 3 depicts a process flow diagram of a deposition process according to one embodiment of the present invention;

FIGS. 4A-C depict schematic cross-sectional views of a substrate structure having a high-k material disposed thereon in accordance with an embodiment in the present invention; and

FIG. 5 depicts a high-k material formed by one embodiment of the present invention having different dielectric constant at different depositing temperature.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention generally provide methods for depositing a high-k dielectric material on a substrate suitable for flash memory fabrication by a chemical vapor deposition process. In some embodiments, the high-k material is an aluminum oxide layer having a dielectric constant greater than 8 deposited by a chemical vapor deposition process, such as a metal-organic chemical vapor deposition process (MOCVD). The aluminum oxide deposited by the MOCVD process provides a high dielectric constant, high erase efficiency and eliminates back tunneling in a TANOS charge trap flash memories.

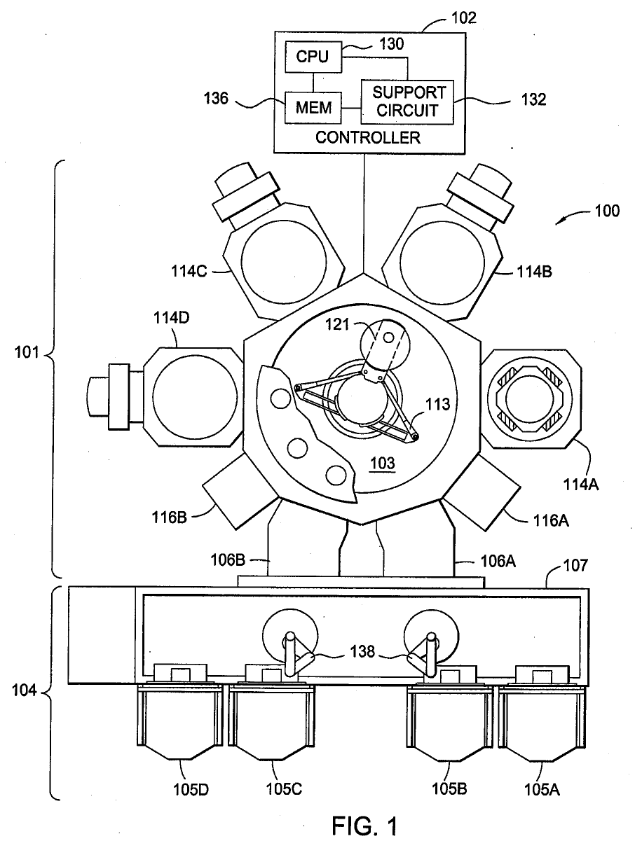

FIG. 1 is a schematic plan view of an integrated tool 100 which may be utilized for processing semiconductor substrates according to embodiments of the present invention. Examples of the integrated tool 100 include the PRODUCER®, CENTURA® and ENDURA® integrated tools, all available from Applied Materials, Inc., of Santa Clara, Calif. It is contemplated that the methods described herein may be practiced in other tools having the requisite process chambers coupled thereto, including those available from other manufacturers.

The tool 100 includes a vacuum-tight processing platform 101, a factory interface 104, and a system controller 102. The platform 101 comprises a plurality of processing chambers 114A-D and load-lock chambers 106A-B, which are coupled to a vacuum substrate transfer chamber 103. The factory interface 104 is coupled to the transfer chamber 103 by the load lock chambers 106A-B.

In one embodiment, the factory interface 104 comprises at least one docking station 107, at least one factory interface robot 138 to facilitate transfer of substrates. The docking station 107 is configured to accept one or more front opening unified pod (FOUP). Four FOUPS 105A-D are shown in the embodiment of FIG. 1. The factory interface robot 138 is configured to transfer the substrate from the factory interface 104 to the processing platform 101 for processing through the loadlock chambers 106A-B.

Each of the loadlock chambers 106A-B have a first port coupled to the factory interface 104 and a second port coupled to the transfer chamber 103. The loadlock chamber 106A-B are coupled to a pressure control system (not shown) which pumps down and vents the chambers 106A-B to facilitate passing the substrate between the vacuum environment of the transfer chamber 103 and the substantially ambient (e.g., atmospheric) environment of the factory interface 104.

The transfer chamber 103 has a vacuum robot 113 disposed therein. The vacuum robot 113 is capable of transferring substrates 121 between the loadlock chamber 106A-B and the processing chambers 114A-D. In one embodiment, the transfer chamber 103 may include cool down station built therein to facilitate cooling down the substrate while transferring substrate in the tool 100.

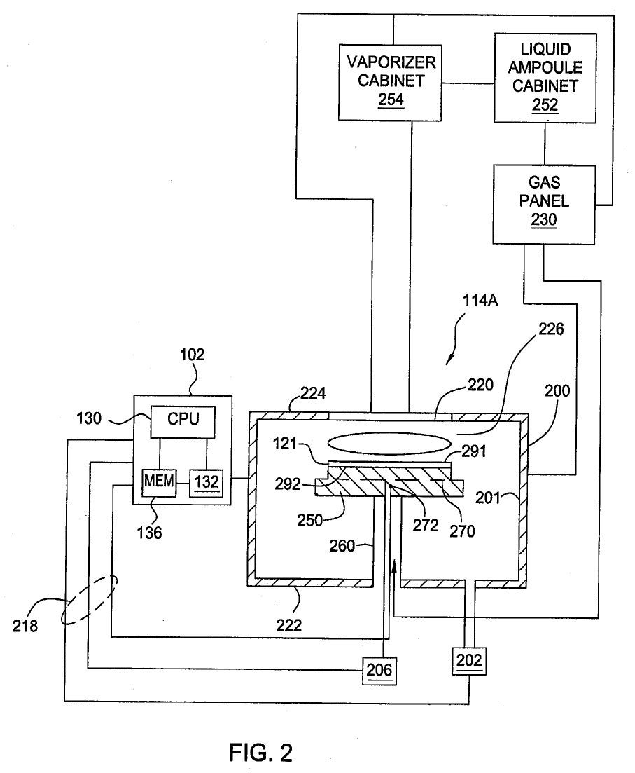

In one embodiment, the processing chambers coupled to the transfer chamber 103 may include a chemical vapor deposition (CVD) chambers 114A-B, a Remote Plasma Oxidation (RPO) chamber 114C, and a Rapid Thermal Process (RTP) chamber 114D. The chemical vapor deposition (CVD) chambers 114A-B may include different types of chemical vapor deposition (CVD) chambers, such as a thermal chemical vapor deposition (Thermal-CVD) process, low pressure chemical vapor deposition (LPCVD), metal-organic chemical vapor deposition (MOCVD), plasma enhanced chemical vapor deposition (PECVD), sub-atmosphere chemical vapor deposition (SACVD) and the like. Alternatively, different processing chambers, including at least one ALD, CVD, PVD, RPO, RTP chamber, may be interchangeably incorporated into the integrated tool 100 in accordance with process requirements. Suitable ALD, CVD, PVD, RPO, RTP and MOCVD processing chambers are available from Applied Materials, Inc., among other manufacturers. In the embodiment depicted in FIG. 1, at least one of the chambers 114A-D in the tool 100 is a MOCVD chamber as will be further discussed in detail below with reference to FIG. 2.

In one embodiment, an optional service chamber (shown as 116A-B) may be coupled to the transfer chamber 103. The service chambers 116A-B may be configured to perform other substrate processes, such as degassing, orientation, pre-cleaning process, cool down and the like.

The system controller 102 is coupled to the integrated processing tool 100. The system controller 102 controls the operation of the tool 100 using a direct control of the process chambers 114A-D of the tool 100 or alternatively, by controlling the computers (or controllers) associated with the process chambers 114A-D and tool 100. In operation, the system controller 102 enables data collection and feedback from the respective chambers and system to optimize performance of the tool 100.

The system controller 102 generally includes a central processing unit, (CPU) 130, a memory 136, and support circuit 132. The CPU 130 may be one of any form of a general purpose computer processor that can be used in an industrial setting. The support circuits 132 are conventionally coupled to the CPU 130 and may comprise cache, clock circuits, input/output subsystems, power supplies, and the like. The software routines, such as a method 200 for high-k dielectric deposition described below with reference to FIG. 2, when executed by the CPU 130, transform the CPU into a specific purpose computer (controller) 102. The software routines may also be stored and/or executed by a second controller (not shown) that is located remotely from the tool 100.

FIG. 2 is a schematic representation of a MOCVD processing chamber, such as the chamber 114A that can be used to perform high-k dielectric material deposition in accordance with embodiments of the present invention. The processing chamber 114A includes a chamber body 200 enclosed by a lid assembly 224. The lid assembly 224, or other portion of the chamber body 200 includes a gas distributor 220 for providing process gas into the chamber 114A. The chamber body 200 generally includes sidewalls 201 and a bottom wall 222 that define an interior volume 226. A support pedestal 250 is provided in the interior volume 226 of the chamber body 200. The pedestal 250 may be fabricated from aluminum, ceramic, and other suitable materials. The pedestal 250 may be moved in a vertical direction inside the chamber body 200 using a displacement mechanism (not shown).

The pedestal 250 may include an embedded heater element 270 suitable for controlling the temperature of a substrate 121 supported thereon. In one embodiment, the pedestal 250 may be resistively heated by applying an electric current from a power supply 206 to the heater element 270. In one embodiment, the heater element 270 may be made of a nickel-chromium wire encapsulated in a nickel-iron-chromium alloy (e.g., INCOLOY® sheath tube. The electric current supplied from the power supply 206 is regulated by the controller 102 to control the heat generated by the heater element 270, thereby maintaining the substrate 121 and the pedestal 250 at a substantially constant temperature during film deposition. The supplied electric current may be adjusted to selectively control the temperature of the pedestal 250 between about 100 degrees Celsius to about 800 degrees Celsius.

A temperature sensor 272, such as a thermocouple, may be embedded in the support pedestal 250 to monitor the temperature of the pedestal 250 in a conventional manner. The measured temperature is used by the controller 102 to regulate the power supplied to the heating element 270 so that the substrate is maintained at a desired temperature.

A vacuum pump 202 is coupled to a port formed in the bottom of the processing chamber 114A. The vacuum pump 202 is used to maintain a desired gas pressure in the processing chamber 114A. The vacuum pump 202 also evacuates post-processing gases and by-products of the process from the processing chamber 114A.

A gas panel 230 is connected to the gas distributor 220 through a liquid ampoule cabinet 252 and a vaporizer cabinet 254. The gas panel 230 introduces gases through the liquid ampoule cabinet 252 and the vaporizer cabinet 254 which carriers a metal precursor from the cabinets 252, 254 to the interior volume 226. One or more apertures (not shown) may be formed in the gas distributor 220 to facilitate gas flowing to the interior volume 226. The apertures may have different sizes, number, distributions, shape, design, and diameters to facilitate the flow of the various process gases for different process requirements. The gas panel 230 may also be connected to the chamber body 200 and/or to the pedestal 250 to provide different paths for supplying gases directly into the interior volume 226, such as fir purge or other applications. Examples of gases that may be supplied from the gas panel include oxygen containing gas, such as, oxygen (O₂), nitrogen (N₂), N₂O, and NO, among others.

The liquid ampoule cabinet 252 may store metal precursor therein which provide source materials used to deposit a metal containing layer on the substrate 121 disposed on the pedestal 250. In one embodiment, the metal precursor may be in a liquid form. Examples of liquid precursor used herein include aluminum containing compounds, such as diethylalumium ethoxide (Et₂AlOEt), triethyl-tri-sec-butoxy dialumium (Et₃Al₂OBu₃, or EBDA), trimethyidialumium ethoxide, or aluminum compounds having a formula of RₓAl_{y}(OR′)_{z}, wherein the x, y, and z are integers having a range between 1 and 8, or Al(NRR′)₃, wherein R and R′ may or may not be the same group, and the like. The gases supplied from the gas panel 230 push the liquid precursor in the ampoule cabinet 252 to the interior volume 226 of the chamber 114A through the vaporizer cabinet 254. The liquid precursor is heated and vaporized in the vaporizer cabinet 254, forming a metal containing vapor which is then injected to the interior volume 226 by the carrier gas. In one embodiment, the vaporizer cabinet 254 may vaporize the liquid precursor at a temperature between about 100 degrees Celsius and about 250 degrees Celsius.

The controller 102 is utilized to control the process sequence and regulate the gas flows from the gas panel 230, the liquid ampoule cabinet 252, and the vaporizer cabinet 254. Bi-directional communications between the controller 110 and the various components of the processing chamber 114A are handled through numerous signal cables collectively referred to as signal buses 218, some of which are illustrated in FIG. 2.

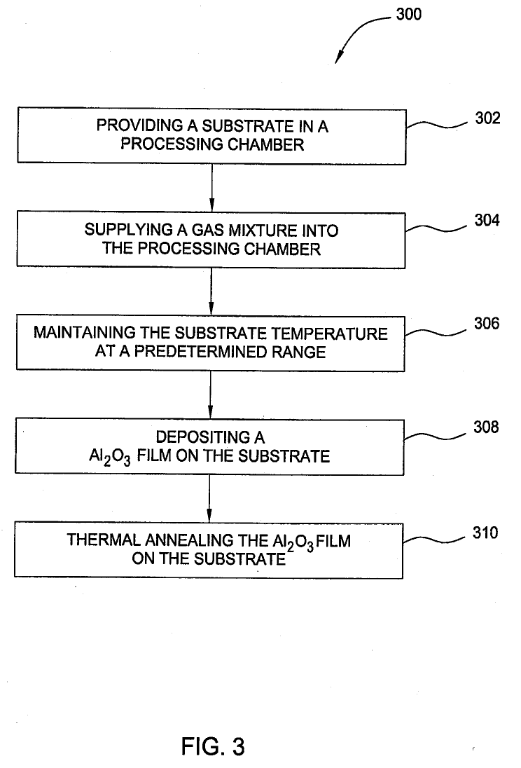

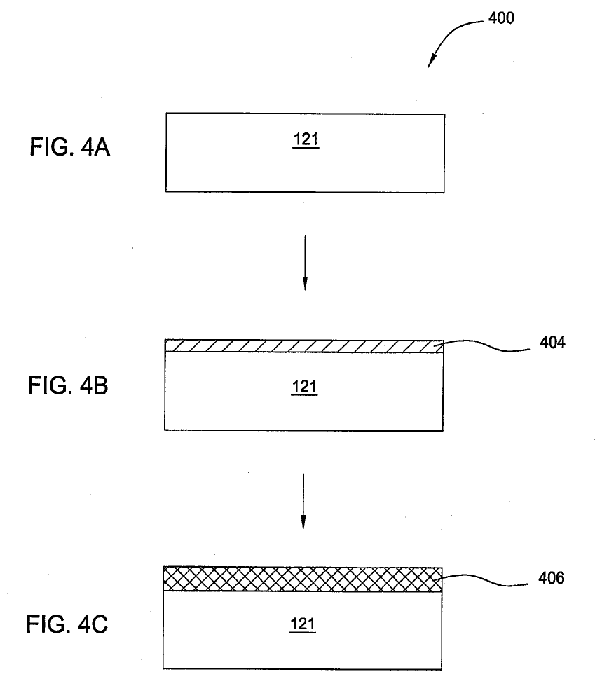

FIG. 3 illustrates a process flow diagram of one embodiment of a process 300 for depositing a high-k material that may be advantageously utilized to form a flash memory stack on a substrate. The high-k material may be deposited in a processing chamber in an integrated cluster tool, such as the processing chamber 114A integrated in the tool 100 described above. It is also contemplated that the method 300 may be performed in other tools, including those from other manufacturers. FIGS. 4A-4C are schematic, cross-sectional views corresponding to different stages of the process 300.

The method 300 begins at step 302 by providing a substrate 121 to a processing chamber, such as the processing chamber 114A in the system 100, to form a high-k dielectric material on the substrate 121 utilized to form a flash memory, as shown in FIG. 4A. The substrate 121 refers to any substrate or material surface upon which film processing is performed. For example, the substrate 121 may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire or other suitable workpieces. The substrate 121 may have various dimensions, such as 200 mm, 300 mm diameter, or 450 mm wafers, as well as, rectangular or square panels. Unless otherwise noted, embodiments and examples described herein are conducted on substrates with a 200 mm diameter, a 300 mm diameter, or a 450 mm diameter.

In one embodiment, the substrate 121 may include a dielectric film stack disposed thereon including a high-k dielectric material that may be suitable for a TANOS charge trap flash memory devices. The dielectric film stack disposed on the substrate 121 includes a silicon nitride layer disposed on a silicon oxide layer. The silicon nitride layer and the silicon oxide layer disposed on the substrate 121 may be deposited by any suitable process.

Prior to transferring the substrate 121 into the processing chamber 114A, a precleaning process may be performed to clean the substrate 121. The precleaning process is configured to cause compounds that are exposed on the surface of the substrate 121 to terminate in a functional group. Functional groups attached and/or formed on the surface of the substrate 121 include hydroxyls (OH), alkoxy (OR, where R=Me, Et, Pr or Bu), haloxyls (OX, where X=F, Cl, Br or I), halides (F, Cl, Br or I), oxygen radicals and aminos (NR or NR₂, where R=H, Me, Et, Pr or Bu). The precleaning process may expose the surface of the substrate 121 to a reagent, such as NH₃, B₂H₆, SiH₄, SiH₆, H₂O, HF, HCI, O₂, O₃, H₂O, H₂O₂, H₂, atomic-H, atomic-N, atomic-O, alcohols, amines, plasmas thereof, derivatives thereof or combination thereof. The functional groups may provide a base for an incoming chemical precursor to attach on the surface of the substrate 121. In one embodiment, the precleaning process may expose the surface of the substrate 121 to a reagent for a period from about 1 second to about 2 minutes. In another embodiment, the exposure period may be from about 5 seconds to about 60 seconds. Precleaning processes may also include exposing the surface of the substrate 121 to an RCA solution (SC1/SC2), an HF-last solution, peroxide solutions, acidic solutions, basic solutions, plasmas thereof, derivatives thereof or combinations thereof. Useful precleaning processes are described in commonly assigned U.S. Pat. No. 6,858,547 and co-pending U.S. patent application Ser. No. 10/302,752, filed Nov. 21, 2002, entitled, “Surface Pre-Treatment for Enhancement of Nucleation of High Dielectric Constant Materials,” and published as US 20030232501, which are both incorporated herein by reference in their entirety.

In embodiments where a wet-clean process is performed to clean the substrate surface, the wet-clean process may be performed in a TEMPEST™ wet-clean system, available from Applied Materials, Inc. Alternatively, the substrate 121 may be exposed to water vapor derived from a WVG system for about 15 seconds.

At step 304, a gas mixture is flowed from the gas panel 230 through the liquid ampoule cabinet 252 and the vaporizer cabinet 254 into the process chamber 114A to the substrate surface. The gas mixture includes at least an aluminum containing compound and a reacting gas to deposit an aluminum oxide (Al₂O₃) layer on the substrate 121. Aluminum oxide (Al₂O₃) layer deposited by the invention method has high thermal stability, high dielectric constant (greater than 8), good electrical resistivity and high purity, making the aluminum oxide (Al₂O₃) layer as a good candidate for use in flash memory fabrication. In one embodiment, the aluminum containing compound may have a formula of RₓAl_{y}(OR′)_{z}, where R and R′ are H, CH₃, C₂H₅, C₃H₇, CO, NCO, alkyl or aryl group and x, y and z are integers having a range between 1 and 8. In another embodiment, the aluminum containing compound may have a formula of Al(NRR′)₃, where R and R′ may be H, CH₃, C₂H₅, C₃H₇, CO, NCO, alkyl or aryl group and R′ may be H, CH₃, C₂H₅, C₃H₇, CO, NCO, alkyl or aryl group. Examples of suitable aluminum containing compounds are diethylalumium ethoxide (Et₂AlOEt), triethyl-tri-sec-butoxy dialumium (Et₃Al₂OBu₃, or EBDA), trimethyldialumium ethoxide, dimethyl aluminum isupropoxide, disecbutoxy aluminum ethoxide, (OR)₂AlR′, wherein R and R′ may be methyl, ethyl, propyl, isopropyl, butyl, isobutyl, tertiary butyl, and other alkyl groups having higher numbers of carbon atoms, and the like. The reacting gas that may be supplied with the aluminum containing gas includes an oxygen containing gas, such as, oxygen (O₂), ozone (O₃), nitrogen (N₂), N₂O, and NO, among others.

In some embodiments, a carrier gas, such as nitrogen (N₂) and nitric oxide (NO), or and/or inert gas, such as argon (Ar) and helium (He), may be supplied with the gas mixture into the processing chamber 114A. Additionally, a variety of other processing gases may be added to the gas mixture to modify properties of the aluminum oxide (Al₂O₃) material. In one embodiment, the processing gases may be reactive gases, such as hydrogen (H₂), ammonia (NH₃), a mixture of hydrogen (H₂) and nitrogen (N₂), or combinations thereof. The addition of different reactive gases or inert gases may change the film structure and/or film chemical components, such as reflectivity, thereby adjusting the deposited film to have a desired film property to meet different process requirements. In the embodiment depicted in the present invention, the aluminum containing compound is triethyl-tri-sec-butoxy dialumium (EBDA) and the reacting gas is oxygen gas (O₂). The carrier gas is nitrogen (N₂) gas.

In one embodiment, triethyl-tri-sec-butoxy dialumium (EBDA) is vaporized at a temperature less than about 150 degrees Celsius, such as about 115 degrees Celsius. Triethyl-tri-sec-butoxy dialumium (EBDA) may be supplied to the processing chamber 114A at a flow rate between about 5 milligram per minute and about 50 milligram per minute. The reacting gas, such as O₂, may be supplied at a flow rate between about 0.1 slm to about 30 slm. The carrier gas, such as N₂, may be supplied at a flow rate between about 0.1 slm to about 10 slm.

At step 306, the substrate temperature of the deposition process is maintained at a predetermined temperature range. In one embodiment, the substrate temperature in the process chamber is maintained between about 500 degrees Celsius and about 900 degrees Celsius, such as about 600 degrees Celsius and about 800 degrees Celsius. In another embodiment, the substrate temperature is maintained between about 600 degrees Celsius and about 700 degrees Celsius.

Several process parameters may be regulated while maintaining the substrate temperature. In one embodiment suitable for processing a 300 mm substrate, the process pressure may be maintained at about 0 Torr to about 80 Torr, for example, about 1 Torr to about 20 Torr, such as about 3.5 Torr. The spacing between the substrate and showerhead may be controlled at about 200 mils to about 1000 mils.

At step 308, an aluminum oxide layer 404 is depositing on the substrate 121, as shown in FIG. 4B, while the aluminum containing compound is decomposed and reacted with the reacting gas. During processing, triethyl-tri-sec-butoxy dialumium (EBDA) is vaporized and carried by the carrier gas, such as, nitrogen (N₂) gas, and/or other different types of inert gas into the processing chamber 114A. The triethyl-tri-sec-butoxy dialumium (EBDA) vapor and the reacting gas, such as O₂, in the chamber 114A react to form the Al₂O₃ film 404 on the substrate 121. The deposition process is performed for a predetermined time period until a desired thickness of the aluminum oxide layer 404 is reached. In one embodiment, the aluminum oxide layer 404 has a thickness between about 125 Å and about 225 Å. The process may be performed for a time period between about 60 seconds and 240 second.

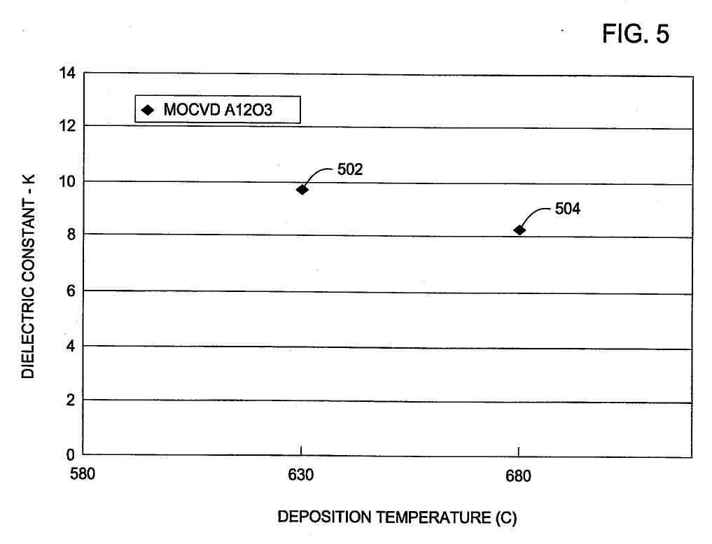

The dielectric constant of the aluminum oxide layer may be adjusted by changing the substrate temperature while depositing. As further depicted in FIG. 5, an aluminum oxide layer deposited at a temperature about 630 degrees Celsius has a dielectric constant about 10 (shown as a dot 502) while deposited at a temperature about 680 degrees Celsius has a dielectric constant about 8 (shown as a dot 504). Accordingly, in embodiments where a lower dielectric constant is desired, a higher process temperature may be utilized to produce a desired lower dielectric constant. In contrast, in embodiments where a higher dielectric constant is desired, a lower process temperature may be utilized to produce a desired higher dielectric constant. Alternatively, the process temperature may be changed in any range to produce different desired dielectric constant.

At an optional step 310, a thermal annealing process may be performed to anneal the high-k aluminum oxide layer 404 disposed on the substrate 121 in an annealing chamber. An example of a suitable RTP chamber in which optional step 310 may be performed is the CENTURA™ RADIANCE™ RTP chamber, available from Applied Materials, Inc., among others. The thermal annealing process step 310 may be sequentially performed in one of the process chambers 114B-D integrated in the tool 100 without breaking vacuum. Alternatively, the thermal annealing process may be performed in different processing chamber in other processing system.

In one embodiment, the substrate 121 may be thermally heated to a temperature from about 700 degrees Celsius to about 1300 degrees Celsius. In another embodiment, the annealing temperature may be controlled from about 800 degrees Celsius to about 1300 degrees Celsius, such as between about 1000 degrees Celsius and about 1300 degrees Celsius. The thermal annealing process may have different durations. In one embodiment, the duration of the thermal annealing process may be from about 1 second to about 180 seconds, for example, about 2 seconds to about 60 seconds, such as about 5 seconds to about 60 seconds. At least one annealing gas is supplied into the chamber for thermal annealing process. Examples of annealing gases include oxygen (O₂), ozone (O₃), atomic oxygen (O), hydrogen (H₂), D₂ gas, water (H₂O), nitric oxide (NO), nitrous oxide (N₂O), nitrogen dioxide (NO₂), dinitrogen pentoxide (N₂O₅), nitrogen (N₂), ammonia (NH₃), hydrazine (N₂H₄), helium (He), argon (Ar), and derivatives thereof or combinations thereof. The process controlled for the anneal is between about 0 and about 760 Torr, such as about 5 Torr and about 100 Torr, for example, about 5 and about 20 Torr.

The optional thermal annealing process of step 310 converts the aluminum oxide layer 404 to a post anneal layer 406, as shown in FIG. 4C. The thermal annealing process step 310 promotes the bonding energy between the aluminum and oxide bonds as measured by a conventional Auger Spectroscopy, thereby providing a solid film structure in the aluminum oxide film. Additionally, the post anneal layer 406 has a smooth surface having a surface roughness less than 5 nm as inspected by a conventional Atomic Force Microscope.

In one embodiment, a metal and/or metal nitride layer, such as Ta or TaN, may be further formed on the top of the post annealed aluminum oxide layer 406 to form a metal gate structure TANOS charge trap flash memory device. The annealed aluminum oxide layer 406 serves as a blocking layer providing high erase efficiency and low power consumption while substantially eliminating back tunneling during erase operations. It is contemplated that the method for depositing the aluminum oxide layer by MOCVD provided herein may also be utilized in other suitable devices and/or transistors.

Thus, methods for depositing a high-k layer that may be used for gate fabrication charge trap flash memories have been provided. The method produces a high dielectric constant stable film serving as a blocking layer in a metal gate structure of TANOS charge trap flash memories, thereby improving electrical performances of the devices.

While the foregoing is directed to embodiments of the invention, other and further embodiments of the invention may be devised without departing from the basic scope thereof, and the scope thereof is determined by the claims that follow.

What is claimed is:

1. A method for forming a high-k dielectric layer on a substrate suitable for flash memory fabrication, comprising:
providing a substrate into a chamber;
supplying a gas mixture containing an oxygen containing gas and an aluminum containing compound into the chamber, wherein the aluminum containing compound has a formula selected from a group consisting of RₓAl_{y}(OR′)_{z} and Al(NRR′)₃;
heating the substrate; and
depositing an aluminum oxide layer having a dielectric constant greater than about 8 on the heated substrate by a chemical vapor deposition process.

2. The method of claim 1, wherein the oxygen containing gas is at least one of O₂, NO, N₂O.

3. The method of claim 1, wherein the step of supplying a gas mixture further comprises:
supplying a carrier gas with the gas mixture.

4. The method of claim 4, wherein the carrier gas is at least one of N₂, Ar, He, NO, N₂O.

5. The method of claim 1, wherein R and R′ of the formula of RₓAl_{y}(OR′)_{z} and Al(NRR′)₃ are at least one of H, CH₃, C₂H₅, C₃H₇, CO, NCO, alkyl and aryl group.

6. The method of claim 1, wherein x, y and z of the formula of RₓAl_{y}(OR′)_{z} are integers having a range between 1 and 8.

7. The method of claim 1, wherein the aluminum containing compound is triethyl-tri-sec-butoxy dialumium (EBDA).

8. The method of claim 1, further comprising:
annealing the substrate.

9. The method of claim 8, wherein the step of annealing further comprises:
supplying an annealing gas; and
annealing the substrate at a temperature between about 700 degrees Celsius and about 1300 degrees Celsius.

10. The method of claim 9, wherein the annealing gas is at least one of N₂, O₂ and H₂.

11. The method of claim 1, wherein the step of supplying the gas mixture further comprises:
vaporizing the triethyl-tri-sec-butoxy dialumium (EBDA) precursor at less than 150 degrees Celsius prior to supplying to the chamber.

12. A method for forming a high-k dielectric layer on a substrate suitable for flash memory fabrication, comprising:
providing a substrate into a chamber;
vaporizing a triethyl-tri-sec-butoxy dialumium (EBDA) precursor at less than 150 degrees Celsius;
supplying vaporized precursor and an oxygen containing gas into the chamber;
heating the substrate; and
depositing an aluminum oxide layer on the heated substrate by a chemical vapor deposition process.

13. The method of claim 12, further comprising:
annealing the substrate at a temperature between about 700 degrees Celsius and about 1300 degrees Celsius.

14. The method of claim 12, wherein the step of heating the substrate further comprises:
heating the substrate at a temperature between about 600 degrees Celsius and about 800 degrees Celsius.

15. The method of claim 13, wherein the step of annealing, further comprising:
supplying an annealing gas to the substrate during annealing, wherein the annealing gas is at least one of N₂, O₂ and H₂.

16. The method of claim 12, wherein the oxygen containing gas is O₂.

17. A method for forming a high-k dielectric layer on a substrate suitable for flash memory fabrication, comprising:
providing a substrate into a chamber;
supplying a gas mixture containing triethyl-tri-sec-butoxy dialumium (EBDA) precursor and an oxygen containing gas into the chamber;
depositing an aluminum oxide layer on the substrate by a chemical vapor deposition process;
heating the substrate to between about 600 degrees Celsius and about 800 degrees Celsius; and
depositing an aluminum oxide layer having a dielectric constant greater than about 8 on the heated substrate by a chemical vapor deposition process.

18. The method of claim 17, wherein the oxygen containing gas is O₂.

19. The method of claim 17, wherein the step of annealing, further comprising:
annealing the substrate at a temperature between about 700 degrees Celsius and about 1300 degrees Celsius.

20. The method of claim 17, wherein the step of annealing, further comprising:
supplying an annealing gas to the substrate during annealing, wherein the annealing gas is at least one of N₂, O₂ and H₂.
